(19) United States
(12) Patent Application Publication
(10) Pub. No.: US 2014/0054065 A1
(43) Pub. Date: Feb. 27, 2014

(54) ELECTRICAL CIRCUIT TRACE MANUFACTURING FOR ELECTRO-CHEMICAL SENSORS

(71) Applicant: Abner D. Joseph, Carmel, IN (US)

(72) Inventor: Abner D. Joseph, Carmel, IN (US)

(21) Appl. No.: 13/590,663

(22) Filed: Aug. 21, 2012

(51) Int. Cl. H05K 3/02; H05K 1/02

(52) U.S. Cl. 174/250; 392/387

(57) ABSTRACT

A method for manufacturing electrical circuit traces for use in electro-chemical sensors is disclosed, as well as electro-chemical sensors made from that method. The method includes providing a web, with a substrate and a thin, electrically conductive portion on the substrate. The web is positioned with a mask between it and a source of high frequency, non-laser photonic energy. The method discloses emitting at least one sub-millisecond burst of high frequency, non-laser photonic energy from said source toward the web with the mask therebetween. The photonic energy is substantially blocked by a photo-opaque portion of the mask. A portion of said non-laser photonic energy transmits with sufficient energy to ablate the portions of the electrically conductive portion exposed to the photonic energy, leaving the circuit traces on the web in the form of a repeating array of traces adapted for use in electro-chemical sensors.

### BACKGROUND

The present invention relates to manufacturing electrical circuit traces, and more specifically to making such traces using non-laser photonic energy.

This method addresses mass manufacturing very low cost, and very consistent circuits. This method may be used to make very high quantity and very low cost flexible circuits that are typically needed for the biosensor (for example blood-glucose sensors and/or otherwise), RFID, and other printed electronics markets.

One method of making very reproducible, consistent and accurate circuits is Laser Ablation. U.S. Pat. No. 6,662,439 explains this method. However, this method cannot make wide web circuits. Typically, lack of enough energy at the substrate due to energy losses in the beam path restricts the maximum web width to around 80 mm.

However, many reel to reel manufacturing processes in the industry typically start at 10 inches (250 mm) and could go up as wide as 60 inches (1500 mm) depending on the levels of accuracy and precision needed to manufacture the product.

The current invention enables circuit manufacturing with broad spectrum, high energy, short pulse duration, photonic energy. As an example, a chrome over glass mask similar to the one used for laser ablation is used to block/transmit photonic energy on the metalized substrate.

The assignee of this application has previously used laser ablation with a one Joule energy excimer laser, optical lenses and a homogenizer to deliver a uniform homogenized laser energy to the substrate. See U.S. Pat. No. 6,662,439. Other prior techniques for manufacturing low cost circuits involve inkjet and plating solutions that, besides being complicated, tend to make the final part almost the same in cost as the laser ablation structures that are made in a narrow web format. See U.S. patent application Ser. No. 12/862,262 for a more complete description of that method. As web widths exceed 10 inches (about 25 centimeters), plating tanks, rinsing tanks and dryers tend to get expensive, complicated and unable to maintain the tolerances needed. Other systems are shown in U.S. Pat. No. 7,820,097 B2, and U.S. Patent Application No. 2009/0159565, and U.S. Patent Application No. 2004/0076376.

Thus, there is a need for improvement in this field of circuit trace manufacturing for electro-chemical sensors.

### SUMMARY

The present inventions are defined by the claims, and only the claims. In summary, this may include a method for manufacturing electrical circuit traces in the form of a repeating array of traces adapted for use in electro-chemical sensors. The method may include providing a web, with a substrate and a thin, electrically conductive portion on the substrate. The web is positioned with a mask between it and a source of high frequency, non-laser photonic energy. There is emitting of high frequency, non-laser photonic energy from the source toward the web with said mask therebetween. The photonic energy is selectively partially blocked by a photo-opaque portion. A portion of said non-laser photonic energy transmits with sufficient energy to leave the circuit traces on the web for use in electro-chemical sensors.

The inventions also include an electro-chemical sensor comprising a circuit trace made from the method.

Further forms, objects, features, aspects, benefits, advantages, and embodiments of the present invention will become apparent from a detailed description and drawings provided herewith.

### BRIEF DESCRIPTION OF THE DRAWINGS

FIG. 1 is a side schematic view illustrating the present method.

FIG. 2 is a plan view of FIG. 1.

FIG. 3A is a plan view, partially cut-away, of portions of a web and a mask.

FIG. 3B is a side view taken along section 3B-3B of FIG. 3A.

FIG. 3C is an alternative to FIG. 3B.

FIG. 4A is a plan view, after ablation, taken along section 4A-4A of FIG. 4B.

FIG. 4B is a side view after ablation.

### DESCRIPTION OF THE SELECTED EMBODIMENTS

For the purpose of promoting an understanding of the principles of the invention, reference will now be made to the embodiments illustrated in the drawings and specific language will be used to describe the same. It will nevertheless be understood that no limitation of the scope of the invention is thereby intended. Any alterations and further modifications in the described embodiments, and any further applications of the principles of the invention as described herein are contemplated as would normally occur to one skilled in the art to which the invention relates. One embodiment of the invention is shown in great detail, although it will be apparent to those skilled in the relevant art that some features that are not relevant to the present invention may not be shown for the sake of clarity.

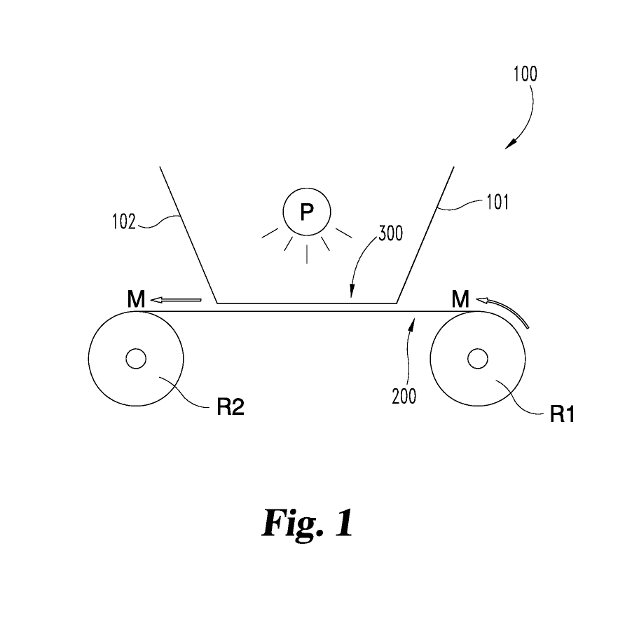

FIGS. 1-5 show mere examples of that which is claimed. Those examples are described here. As used in the claims and the specification, the following terms have the following defined meanings:

As used herein the term “ablating” means the removing of material from or along the surface of something. This includes the use of heat, vaporization and/or removal as plasma.

As used herein the term “ablation gas” means the combination of gases and suspended plasma, metal(s), particles, dust created by ablation.

As used herein the term “average burst frequency” means the statistical average number of bursts per second, typically calculated on the basis of the duration of time between one burst peak and the next burst peak during operation.

As used herein the term “array” means a selective arrangement of circuit traces.

As used herein the term “burst” means a short pulse of a photonic energy. This may be a strobe pulse or otherwise. Normally, the light is applied only for short durations, typically between about 100 microseconds and 1 millisecond.

As used herein the term “circuit trace” means an electrically conductive path used as part of an electrical circuit. Typically, such traces are thin and comprise conductive metal supported on a substrate.

As used herein the term “corresponding in profile” means having the outline shape of the circuit traces to be made.

As used herein the term “electrical circuit device” means a device incorporating one or more circuit traces and which are for use with, in or as part of electrical devices.

As used herein the term “electro-chemical sensor” means an electrical circuit device for use in measuring electrical current and/or signal flow through a fluid resulting from an applied electrical signal upon or after a redox reaction occurs within the fluid, where the fluid spans at least portions of at least two electrically isolated circuit traces, for example blood-glucose sensors and/or otherwise.

As used herein the term “electrically conductive portion” means a layer or other portion (non-layer, multi-layers, overlapping structures, regions, or otherwise) of material(s) on or in something else (substrate, device, otherwise) which has sufficient electrical conductivity to function proficiently for an electrical circuit device. It typically is a two-dimensional portion, although it may be three dimensional, shaped, curved, serpentine and/or otherwise. It may be made of any one or more materials, including without limitation, copper, aluminum, gold, palladium, silver, carbon and/or otherwise (metal and/or non-metal). It may be alloyed, blended, printed, sintered, sub-portioned, conductive inks, solder mask printing and/or otherwise.

As used herein the term “electro-statically recovering” means using one or more positively and/or negatively charged surfaces to attract and collect gas-borne and/or suspended vapors, particles and/or plasma.

As used herein the term “flexible” means sufficiently non-rigid that it may be wound around a roll without breaking.

As used herein the term “high frequency, non-laser photonic energy” means energy, (such as measured in Joules or milli-Joules) in the initial form of predominantly non-laser light, the majority of such light having a wavelength less than about 1,000 nanometers. Often, the majority of such light has a wavelength between about 200 and 1,000 nanometers

As used herein the term “high-energy broad spectrum light” means light, (visible, invisible, or both) in the electromagnetic spectrum having: (a) an energy at or greater than about 180 Joules, and optionally greater than about 2000 joules; and, (b) having more than one wavelength of light having a frequency variance of at least about 180 nanometers, and optionally a frequency variance of at least 1100 nanometers apart. This may, but does not necessarily include high frequency, non-laser photonic energy and/or pulse forging.

As used herein the term “non-optical” means not using any concave and/or convex lens. Mere refraction, such as light passing into and out of a photo-transmissive layer that has generally parallel outer surfaces (e.g. both surfaces flat) is included within the meaning of this term “non-optical”.

As used herein the term “photo-opaque portion” means a layer or other portion (non-layer, multi-layers, overlapping structures, regions, or otherwise) which reflects and/or absorbs most or all of high frequency, non-laser photonic energy directed at it sufficient to substantially prevent ablation of electrically conductive portions on a substrate positioned opposite the photo-opaque portion from a source of such energy.

As used herein the term “photo-transmissive portion” means a layer or other portion (non-layer, multi-layers, overlapping structures, regions, or otherwise) which does not substantially reflect and/or absorb high frequency, non-laser photonic energy directed at it, allowing substantial ablation of electrically conductive portions on a substrate positioned opposite the photo-transmissive portion from a source of such energy.

As used herein the term “reflective metal portion” means a portion of a photo-opaque portion comprising a layer or other portion (non-layer, multi-layers, overlapping structures, regions, or otherwise) which reflects most all of high frequency, non-laser photonic energy directed at it sufficient to substantially prevent ablation of electrically conductive portions on a substrate positioned opposite the reflective metal portion from a source of such energy.

As used herein the term “repeating array” means more than one array, as previously defined, repeated along the length of a web or substrate, typically in one or more row(s) and/or column(s).

As used herein the term “substrate” means a layer or other structure(s) which are below and support (directly and/or indirectly) another portion, layer and/or traces. It may be flexible and/or non-flexible and typically comprises an insulative, non-conductive material.

As used herein the term “vaporized metal” mean metal that has been heated to vapor, gas borne suspended liquid droplet and/or plasma state.

As used herein the term “web” means a portion and/or portions having a width substantially greater than its thickness, and having a length greater than its width. It may be a substrate and/or include a substrate. It may be flexible and/or non-flexible.

As used herein the term “width” means the wide or transverse dimension of a web, taken perpendicular to its longitudinal direction of movement.

The term “and/or” means, inclusively, both “and” (conjunctive) as well as “or” (disjunctively). Articles and phases such as, “the”, “a”, “an”, “at least one”, and “a first”, are not limited to mean only one, but rather are inclusive and open ended to also include, optionally, multiple such element(s) and/or act(s). Likewise, “comprising” is open ended and inclusive. As used herein the term “consisting essentially” means for the recited act(s) and/or element(s) plus, optionally, only additional acts or elements which do not materially affect the basic and novel properties of the invention.

Other than as defined expressly above, terms have the meaning and scope as defined by all consistent dictionary definitions found in Merriam-Webster's Collegiate Dictionary, Eleventh Edition and/or The American Heritage Dictionary of the English Language, Fourth Edition.

With reference to the drawing FIGS. 1-5, various examples are shown and described.

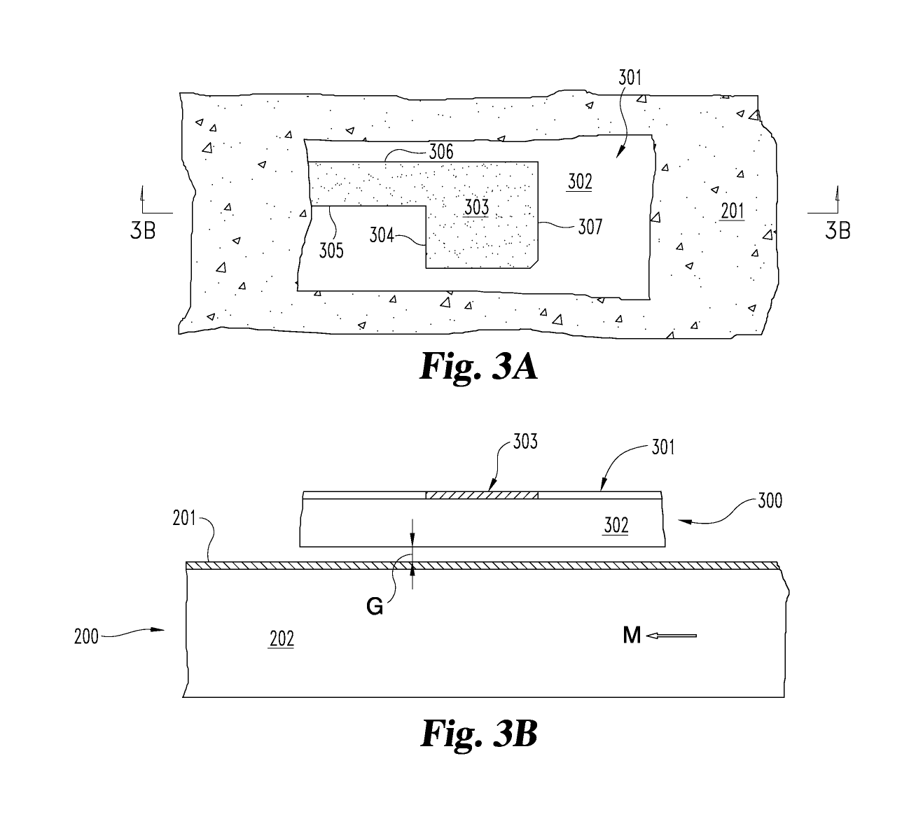

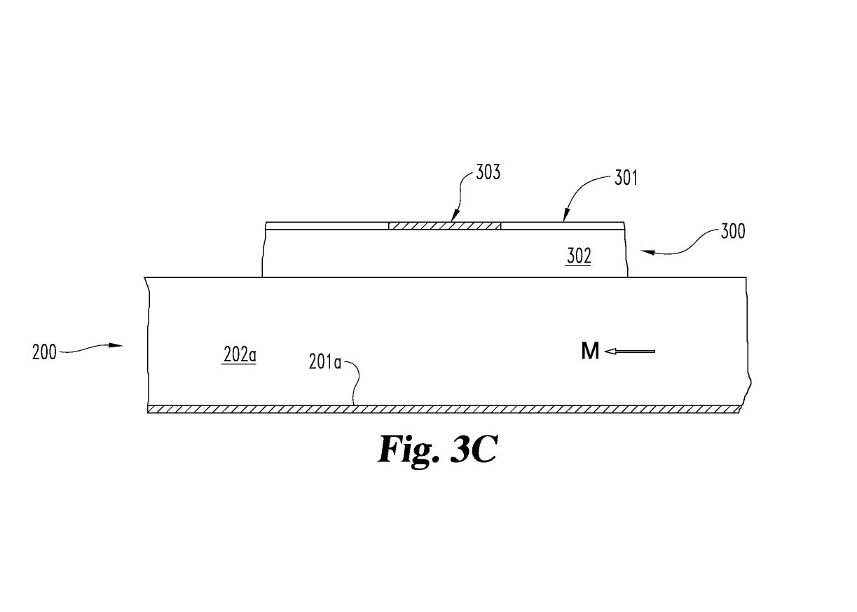

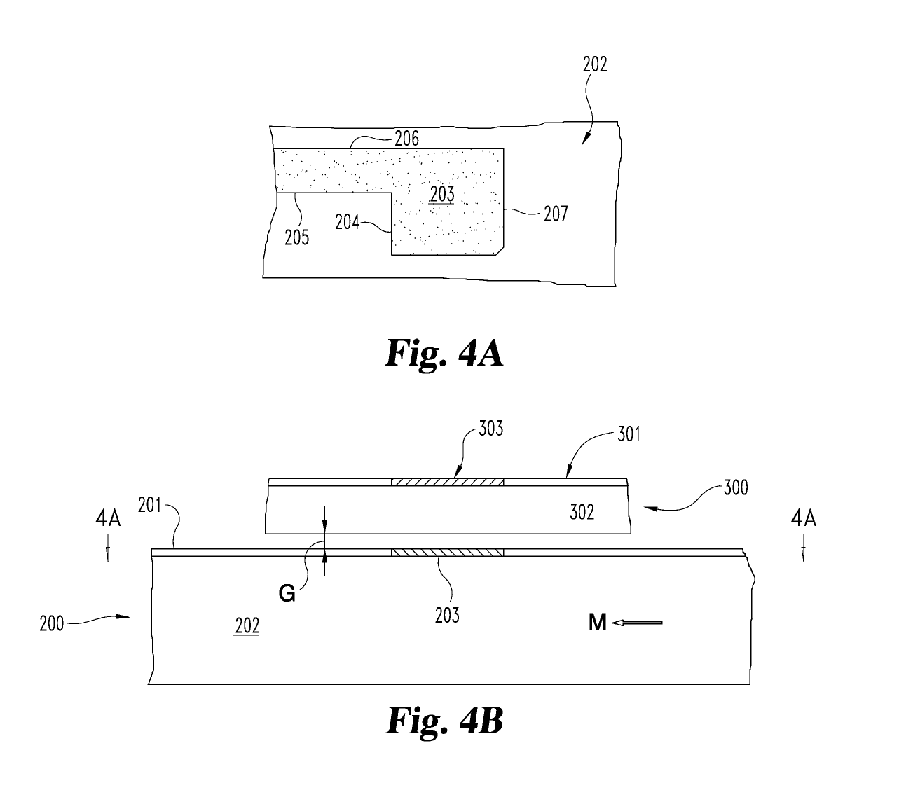

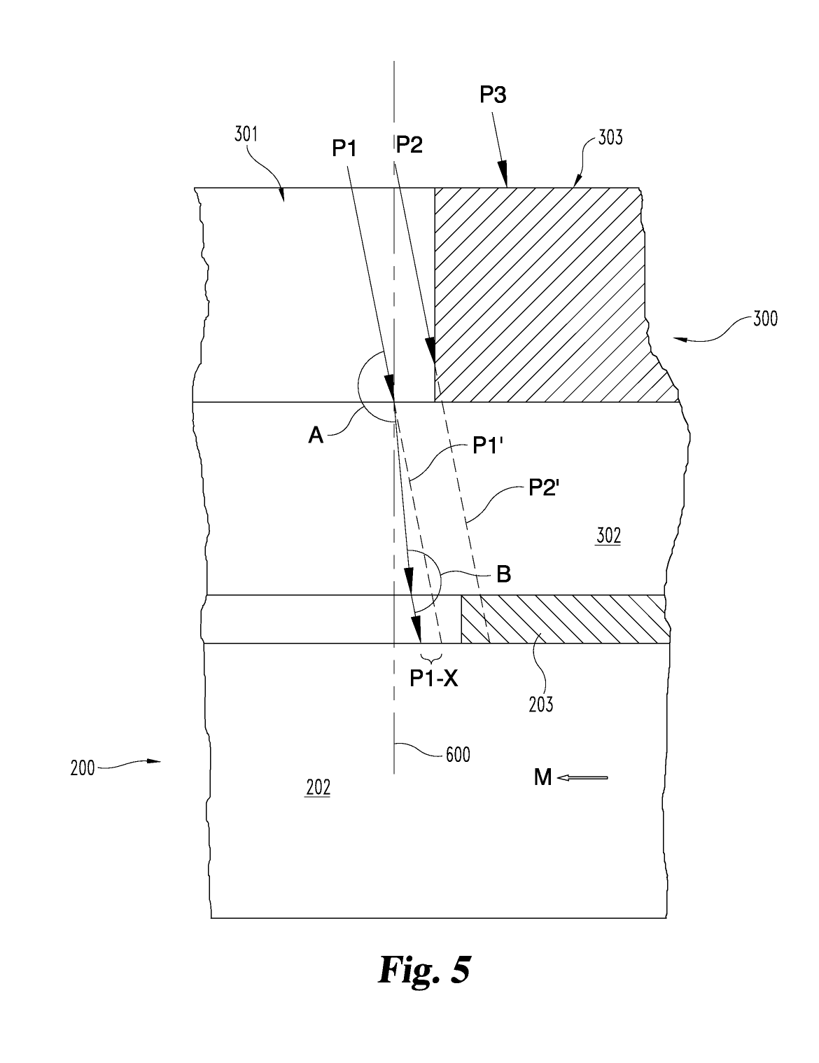

For example, they show method 100 for manufacturing electrical circuit traces 203 in the form of a repeating array of traces adapted for use in electro-chemical sensors. This may comprise the acts of providing a web 200 comprising a substrate 202 and a thin, electrically conductive portion 201 on said substrate. The web is positioned with a mask 300 between it and a source P of high frequency, non-laser photonic energy. The mask may comprise a pattern defined by one or more photo-transmissive portions 302 and one or more photo-opaque portions 303. In one embodiment, the mask comprises a layer or other portion of photo-transmissive material having a pattern of a photo-opaque portion thereon. In further embodiments, the photo-opaque portion is provided on a side of the photo-transmissive material opposite the web, such as illustrated in FIG. 3B. Optionally, portion 303 may be inverted such that it is located on the bottom, directly facing the web (not shown). Optionally, portion 303 may be sandwiched between photo-transmissive material 302 and another portion, such as for example another photo-transmissive portion(s) (not shown) over portion 303. The photo-opaque portion, which optionally is reflective, corresponds in profile to the circuit traces to be manufactured. As but one example, such corresponding profile is seen by comparing FIG. 3A and its mask edges 304, 305, 306, and 307 with FIG. 4A and its corresponding trace edges 204, 205, 206 and 207. Any shape(s) and geometries may be used. The method includes emitting at least one sub-millisecond burst of high frequency, non-laser photonic energy (see e.g. beams P1, P2 and P3 in FIG. 5) from a source, for example schematically shown as P (FIG. 1), toward the web 200 with the mask 300 therebetween. The non-laser photonic energy is substantially blocked from said electrically conductive portion 203 by said photo-opaque portion 303. Examples are shown with beams P2 and P3 (see FIG. 5) blocked. Path P2′ shows where beam P2 would have gone absent blocking.

A portion of said non-laser photonic energy transmits through said photo-transmissive material 302 with sufficient energy to ablate a portion of said conductive portion (see e.g. FIGS. 4A, 4B and 5) and to leave the circuit traces 203 on a web. If and as the web advances to a next position, the process is repeated such that a plurality of circuit traces 203 are left on the web, in the form of a repeating array of traces adapted for use in electro-chemical sensors.

Optionally, there is relative movement between the web and the mask. Such movement may be substantially constant, or may be intermittent (with movement stopped or slowed during ablating). However, instead of movement one may employ stationary batch processing.

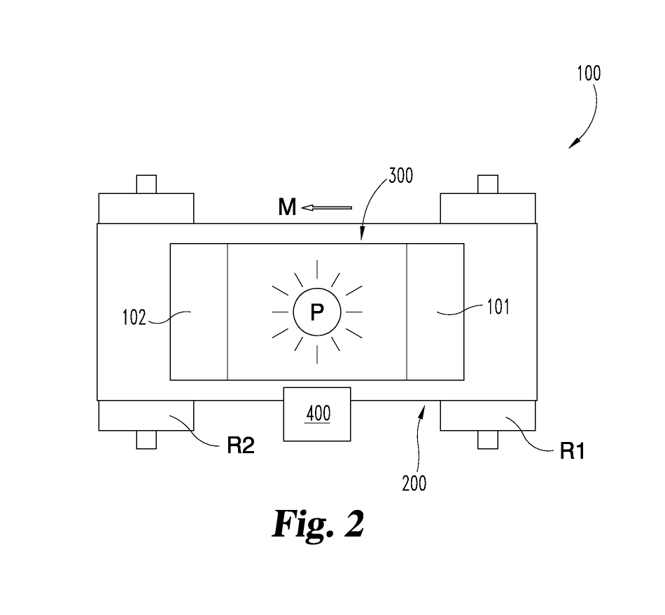

Optionally, mask 300 is stationary and the web 200 moves M past and parallel to the mask. Or, the mask could be moved, or both the mask and the web moved, but these are less preferred. Optionally, the non-laser photonic-energy transmits through said solid, photo-transmissive portion, 302 at 301, of the mask and there is a gap G between the solid portion the said electrically conductive portion of said web. This may provide a gap which allows liberation of ablation gas from said conductive portion 201. Optionally, the method may use means 400 (see FIG. 2) for electro-statically recovering vaporized metal among said ablation gas from the gap G. Optionally, in addition to electro-static recovery, unit(s) 400 may, via compression and/or suction, induce air/gas flow through gap G to enhance removal of ablation gas and vaporized material (e.g. metal) therein.

Optionally, the photo-transmissive material 302 of the mask has an index of refraction which is higher than the index of refraction of the ambient environment (for example, just above window 301 in FIG. 5) adjacent to 302 on a side away from the web 200. This may provide the photo-energy P1 being refracted at an angle A closer to perpendicular (see perpendicular (and normal) reference line 600 in FIG. 5) to the web while beam P1 transmits through said solid, photo-transmissive material 302. Note that FIG. 5 shows an alternative without gap G. With or without gap G, if the media (often gas) in the gap (for example gas replacing ablated portion 201) has the same index of refraction as the ambient above the mask, the refraction leaving material 302, angle B, should be at or near equal to angle A (with both angle A and angle B being less than 180 degrees). With or without such gap, the net effect of such refraction may be to provide the photo-energy P1 being refracted closer to perpendicular 600. This may enhance line resolution of the trace edges, particularly with respect to non-perpendicular beams. By comparison, dashed projection line P1′ (FIG. 5) illustrates what path P1 would have taken without such refraction through solid material 302, showing path offset P1-X between P1 and P1′. Note also that normally the top and bottom surfaces of material 302 are flat and parallel to each other, but optionally may be curved or otherwise. Optionally, the mask is in close proximity, and in some cases touching, the web and/or the conductive portion of the web.

Material choices may vary. For example, optionally, the mask substrate 302 may comprise quartz, glass, or otherwise (tinted or not); the photo-opaque portion 303 may comprise a reflective metal portion, including without limitation for example, chrome, or chromium, and/or alloys and/or blends thereof. The conductive portion 201 is as defined, and may include for example metals and/or other conductors, including without limitation copper, aluminum, gold, silver, palladium, carbon and/or alloys, blends, laminates and/or sintering combinations thereof.

The present method may provide for mass and rapid production. For example, web widths and movement speeds may be high. A repeating array of electro-chemical sensor trace patterns may be mass produced. A majority of the photonic energy may be between about 200 and 800 nanometers in wavelength. Optionally, the web has a width (transverse to the direction of movement M in FIG. 2) which is greater than 10 centimeters, and/or greater than 25 centimeters, and/or at or greater than one meter, and/or at or greater than one and one-half meters (1500 mm). Optionally, the repeating array comprises one or more rows and/or columns of the array on the web.

If there is movement, the web may move M at speeds in excess of zero, in excess of ten meters per second, and even up to around 50 meters per second and potentially faster. Emitting from P (such as from photonic curing lamps or otherwise) may comprise repeated bursts of energy at an average burst frequency greater than 30 bursts per second. The rapid bursts may, without stopping fast movement M, be so fast that a batch or array of traces (including trace patterns) may be ablated, nearly instantaneously, with good resolution. Then, as the web moves, the next burst is timed to coincide with such ablated array having moved past the mask, presenting new un-ablated web under the mask for the next ablation to create a series of repeating arrays. In this sense, the method may provide a rapid, continuous process yet with “batch” processes therein with each ablation burst. The speed of movement typically is adjusted to provide a trade-off between production speed and the resolution or acuity of trace edges. This tends to be a function of movement speed and burst duration. As but one prophetic example, if the mask were stationary and the web is moved at 15 meters per minute, and if the burst of energy had a duration of 200 microseconds (0.0002 seconds), then the linear amount of web moving past a stationary portion of the mask would be about 0.05 millimeters during the burst (15,000 millimeters/minute X 0.0002 seconds X (1 minute/60 seconds)=0.05 millimeters). As but another prophetic example, if the mask were stationary and the web is moved at (or slowed to) 100 meters per minute, and if the burst of energy had a duration of 20 microseconds (0.00002 seconds), then the linear amount of web moving past a stationary portion of the mask would be about 0.067 millimeters (0.2 millimeters) during the burst (100,000 millimeters/minute X 0.00002 seconds X (1 minute/60 seconds)=0.067 millimeters). That would affect the resolution or acuity of trace edges that were transverse along the web and perpendicular to the direction of movement M. Conversely, trace edges that are parallel to the direction of movement are subject less or no such effect from movement M; hence, its is optionally preferable to arrange traces within the arrays with edges whose resolution and/or acuity need to be held more precisely, such as with traces spaced closely together, such that those trace edges run parallel to the direction of movement M. Stationary (no movement M) operation, by batch processing or by stopping movement M during energy bursts, leads to optimal resolution and acuity of trade edges and traces corresponding to the mask. Nevertheless, the practical implementation of such a stationary operation, particularly by stopping movement during energy bursts, can be complicated and difficult to achieve in view of machine tolerances to be accounted for with regard to constant and rapid stopping and starting of a reel-to-reel web process, which may cause such intermittent movement of the web from one desired location to the next location less precise and reproducible than more constant movement of the web under optimized parameters of web speed and burst duration.

Optionally, the traces from this method may be combined with traces made from other methods, including inkjet printing, flexo/gravure printing, more conventional trace making methods, and otherwise. These also may be interleaved and/or otherwise be made in three dimensional arrangements with respect to each other and/or portion of traces, including sequential laminating and/or other processing using the various methods. These options here may also include other ablation methods, including laser ablation methods, such as also using laser ablation on selected traces and/or at selected locations.

Note that in FIGS. 1 and 2 source P is schematically shown at a single location, although it can and normally would comprise a plurality of photonic emitters, such as in row(s) and/or array(s). Optional baffles 101 and/or 102 and otherwise (FIG. 1) may be provided to confine and/or redirect light and/or to facilitate electro-static recovery of ablated metals. The flexible web may be supplied from a supply roll R1 and wound on an output roll R2, although non-roll sheet handling and/or cutting may be undertaken instead or and/or in addition to rolling.

Optionally, rather than having the conductive portion 201 between the mask and the web substrate 202, it may be inverted such that the web substrate 202a is both: (a) between the mask 300 and the conductive portion 201a and; (b) photo-transmissive. See FIG. 3C. In such arrangement, the non-laser photonic energy may transmit through the web substrate to substantially ablate the conductive portion 201a. Optionally, in such arrangement, this may be done with or without the aforementioned gap G (e.g. substrate 202a may be in contact with mask 300). Ablation gas recovery may be on the side of the web opposite of the mask and photonic energy source. Also optionally, this may be done with or without a solid, photo-transmissive material 302 of the mask, such as for example, by simply having openings 301 in the mask with the photo-opaque portions 303 being sufficiently thick and strong to be self-supporting without a photo-transmissive portion of the mask.

While the invention has been illustrated and described in detail in the drawings and foregoing description, the same is to be considered as illustrative and not restrictive in character, it being understood that only some embodiment has been shown and described and that all changes, equivalents, and modifications that come within the spirit of the inventions defined by following claims are desired to be protected. All publications, patents, and patent applications cited in this specification are herein incorporated by reference as if each individual publication, patent, or patent application were specifically and individually indicated to be incorporated by reference and set forth in its entirety herein.

1. A method for manufacturing electrical circuit traces, comprising the acts of:
providing a web, said web comprising a substrate and a thin, electrically conductive portion on said substrate;
positioning said web with a mask between it and a source of high frequency, non-laser photonic energy;
said mask comprising a pattern defined by one or more photo-transmissive portions and one or more photo-opaque portions, said photo-opaque portions corresponding in profile to the circuit traces to be manufactured;
emitting at least one sub-millisecond burst of high frequency, non-laser photonic energy from said source toward said web with said mask therebetween;
wherein said non-laser photonic energy is substantially blocked from said electrically conductive portion by said photo-opaque portions;
wherein a portion of said non-laser photonic energy transmits through said one or more photo-transmissive portions with sufficient energy to ablate a portion of said conductive portion and to leave the circuit traces on said web.

2. The method of claim 1 wherein said non-laser photonic-energy comprises high-energy broad spectrum light.

3. The method of claim 1 wherein said photo-transmissive portion of said mask has an index of refraction which is higher than the index of refraction of the ambient environment adjacent to it on a side away from said web, whereby said photo-energy is refracted at an angle closer to perpendicular to said web while it transmits through said photo-transmissive portion.

4. The method of claim 1 wherein the act of positioning includes positioning the web and the mask with a gap therebetween, wherein said ablation of a portion of said conductive portion creates ablation gas from said conductive portion, and wherein said gap allows liberation of ablation gas.

5. The method of claim 1 wherein said mask is maintained generally stationary and said web moves past and parallel to said mask, wherein said ablation leaves a first array of circuit traces on said web, and further comprising the act of moving the web and repeating the act of emitting, wherein circuit traces are left on said web in the form of a repeating array of traces.

6. The method of claim 1 wherein said act of emitting comprises repeated bursts of energy at an average burst frequency greater than 30 bursts per second.

7. The method of claim 1 wherein a majority of said photonic energy is between about 200 and 800 nanometers in wavelength.

8. The method of claim 1 wherein the one or more photo-transmissive portion of said mask is non-optical.

9. The method of claim 1 wherein said photo-opaque portion comprises a reflective metal portion.

10. The method of claim 9 wherein said photo-opaque portion includes at least one of the group consisting essentially of: chrome, chromium, alloys thereof and blends thereof.

11. The method of claim 1 wherein said web has a width which is greater than about twenty-five centimeters.

12. The method of claim 5 wherein said web is flexible and moves at speeds in excess of ten meters per minute.

13. The method of claim 4 and further comprising means for electro-statically recovering vaporized metal among said ablation gas from said gap between said solid portion and said electrically conductive portion.

14. The method of claim 1 wherein said act of emitting comprises repeated bursts of energy at an average burst frequency greater than 30 bursts per second; wherein a majority of said photonic energy is between about 200 and 800 nanometers in wavelength; and wherein the one or more photo-transmissive portion of said mask is non-optical.

15. The method of claim 14 wherein said photo-opaque portion comprises a reflective metal portion comprising at least one of the group consisting essentially of: chrome, chromium, alloys thereof and blends thereof.

16. The method of claim 15 wherein the act of positioning includes positioning the web and the mask with a gap therebetween, wherein said ablation of a portion of said conductive portion creates ablation gas from said conductive portion, and wherein said gap allows liberation of ablation gas and further comprising means for electro-statically recovering vaporized metal among said ablation gas from said gap between said solid portion and said electrically conductive portion.

17. The method of claim 14 wherein said web has a width which is greater than about twenty-five centimeters.

18. The method of claim 17 wherein said mask is maintained generally stationary and said web moves past and parallel to said mask, wherein said ablation leaves a first array of circuit traces on said web, and further comprising the act of moving the web and repeating the act of emitting, wherein circuit traces are left on said web in the form of a repeating array of traces and wherein said web is flexible and moves at speeds in excess of ten meters per minute.

19. The method of claim 14 wherein said photo-transmissive portion of said mask has an index of refraction which is higher than the index of refraction of the ambient environment adjacent to it on a side away from said web, whereby said photo-energy is refracted at an angle closer to perpendicular to said web while it transmits through said photo-transmissive portion.

20. An electro-chemical sensor comprising a circuit trace made from the method of claim 1.

21. A method for manufacturing electrical circuit traces, comprising the acts of:
providing a web, said web comprising a substrate and a thin, electrically conductive portion on said substrate, said substrate being photo-transmissive;
positioning said web with a mask between it and a source of high frequency, non-laser photonic energy, wherein said web has said photo-transmissive substrate between said mask and said conductive portion;
said mask comprising a photo-opaque portion, said photo-opaque portion corresponding in profile to the circuit traces to be manufactured;
emitting at least one sub-millisecond burst of high frequency, non-laser photonic energy from said source toward said web with said mask therebetween;
wherein said non-laser photonic energy is substantially blocked by said photo-opaque portion from said electrically conductive portion;
wherein a portion of said non-laser photonic energy transmits through said photo-transmissive web substrate with sufficient energy to ablate a portion of said conductive portion and to leave the circuit traces on said web.

22. The method of claim 27 wherein said mask further comprises a photo-transmissive portion.

23. An electro-chemical sensor comprising a circuit trace made from the method of claim 27.
